(19) United States
(12) Patent Application Publication
(10) Pub. No.: US 2016/0167083 A1
(43) Pub. Date: Jun. 16, 2016

(54) MASK FRAME ASSEMBLY AND METHOD OF MANUFACTURING THE SAME

(71) Applicant: SAMSUNG DISPLAY CO., LTD., Yongin-City (KR)

(72) Inventors: Jeunghoon Kim, Yongin-City (KR); Yoonchan Oh, Yongin-City (KR); Jangwoo Kim, Yongin-City (KR); Heeseak Noh, Yongin-City (KR); Bongjun Park, Yongin-City (KR); Taeyong An, Yongin-City (KR); Daesik Jang, Yongin-City (KR); Cheolgyu Jeong, Yongin-City (KR); Jaemin Hong, Yongin-City (KR)

(21) Appl. No.: 14/719,155

(22) Filed: May 21, 2015

(30) Foreign Application Priority Data
Dec. 16, 2014 (KR) 10-2014-0181616

(51) Int. Cl. B05C 21/00; B05B 15/04

(52) U.S. Cl. CPC B05C 21/005; B05B 15/045

(57) ABSTRACT

A mask frame assembly includes a frame and a mask including a pattern portion having a pattern hole and a shape memory alloy portion. A method of manufacturing a mask frame assembly includes forming a pattern portion having a pattern hole and a shape memory alloy portion on a mask, the shape memory alloy portion extending in a first direction at a deposition temperature, and coupling the mask to a frame by extending the mask at a room temperature in a second direction perpendicular to the first direction.

### CROSS-REFERENCE TO RELATED APPLICATION

This application claims priority to and the benefit of Korean Patent Application No. 10-2014-0181616, filed on Dec. 16, 2014, in the Korean Intellectual Property Office, the disclosure of which is incorporated herein in its entirety by reference.

### BACKGROUND

1. Field

One or more exemplary embodiments relate to a mask frame assembly used in deposition of thin films and a method of manufacturing the mask frame assembly.

2. Description of the Related Art

In general, an organic light emitting display apparatus is a display apparatus that forms an image as holes and electrons injected into an anode and a cathode recombine in an emissive layer, and has a stacked layer structure in which the emissive layer is inserted between the anode and the cathode. However, it is difficult to obtain high-efficiency emission, and thus an electron injection layer, an electron transport layer, a hole transport layer, or a hole injection layer or the like is selectively added as an intermediate layer with the emissive layer between the two electrodes.

The electrodes and the intermediate layers of an organic light emitting display apparatus may be formed using various methods, including a deposition method. When manufacturing an organic light emitting display apparatus by using a deposition method, a mask frame having the same pattern as a pattern of a thin film to be formed is aligned on a substrate, and a raw material of the thin film is deposited on the substrate through the mask frame assembly to form the thin film of a desired pattern.

### SUMMARY

One or more exemplary embodiments include a mask frame assembly and a method of manufacturing the mask frame assembly.

However, the one or more embodiments described herein are only examples, and the scope of the present invention is not limited thereto.

Additional aspects will be set forth in part in the description which follows and, in part, will be apparent from the description, or may be learned by practice of the presented embodiments.

According to one or more exemplary embodiments, a mask frame assembly includes: a frame and a mask extending in a first direction at a room temperature and coupled to the frame, wherein the mask includes a pattern portion having a pattern hole and a shape memory alloy portion that extends at a deposition temperature.

The shape memory alloy portion may extend at the deposition temperature in a second direction perpendicular to the first direction.

The mask may include a plurality of pattern portions and a plurality of shape memory alloy portions.

The plurality of shape memory alloy portions may be between adjacent ones of the plurality of pattern portions.

The room temperature may be between about 20° C. and about 25° C., and the deposition temperature may be between about 40° C. and about 80° C.

The shape memory alloy portion may include a nickel-titanium alloy material.

According to one or more exemplary embodiments, a method of manufacturing a mask frame assembly includes: forming a pattern portion having a pattern hole and a shape memory alloy portion on a mask, the shape memory alloy portion extending in a first direction at a deposition temperature; and coupling the mask to a frame by extending the mask at a room temperature in a second direction perpendicular to the first direction.

A plurality of pattern portions and a plurality of shape memory alloy portions may be formed on the mask in an alternating pattern.

The room temperature may be between about 20° C. and about 25° C., and the deposition temperature may be between about 40° C. and about 80° C.

The shape memory alloy portion may include a nickel-titanium alloy material.

### BRIEF DESCRIPTION OF THE DRAWINGS

These and/or other aspects will become apparent and more readily appreciated from the following description of the exemplary embodiments, taken in conjunction with the accompanying drawings in which:

FIG. 1 is a schematic view of a deposition operation performed using a mask frame assembly according to an embodiment of the present invention;

FIG. 2 is a disassembled perspective view of the mask frame assembly of FIG. 1;

FIG. 3 is a plan view illustrating an operation of coupling a mask of the mask frame assembly illustrated in FIG. 2 to a frame;

FIG. 4 is a plan view illustrating an operation in which the mask of FIG. 3 is flattened due to deformation of a shape memory alloy portion at a deposition temperature;

FIG. 5 is a cross-sectional side view illustrating a structure of an organic light emitting display apparatus that may be manufactured using the mask frame assembly illustrated in FIG. 1; and

FIG. 6 is a plan view of the mask frame assembly of FIG. 1 according to another embodiment of the present invention.

### DETAILED DESCRIPTION

Reference is made herein to exemplary embodiments of the present invention, examples of which are illustrated in the accompanying drawings, wherein like reference numerals refer to like elements throughout. In this regard, the present exemplary embodiments may have different forms and should not be construed as being limited to the descriptions set forth herein. Accordingly, the exemplary embodiments are merely described below, by referring to the figures, to explain aspects of the present description. Expressions such as “at least one of,” when preceding a list of elements, modify the entire list of elements and do not modify the individual elements of the list.

As the invention allows for various changes and numerous embodiments, particular embodiments are illustrated in the drawings and described in the written description. Hereinafter, effects and features of the present invention and a method for accomplishing them are described more fully with reference to the accompanying drawings, in which exemplary embodiments of the invention are shown. This invention may, however, be embodied in many different forms and should not be construed as limited to the exemplary embodiments set forth herein.

One or more embodiments of the invention are described below with reference to the accompanying drawings. Those components that are the same or are in correspondence are rendered with the same reference numeral regardless of the figure number, and redundant explanations are omitted.

As used herein, the singular forms “a”, “an”, and “the” are intended to include the plural forms as well, unless the context clearly indicates otherwise.

It will be further understood that the terms “including” or “having” used herein specify the presence of stated features or components, but do not preclude the presence or addition of one or more other features or components.

It will be understood that when a layer, region, or component is referred to as being “formed on” another layer, region, or component, it can be directly or indirectly formed on the other layer, region, or component. That is, for example, intervening layers, regions, or components may be present.

Sizes of elements in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

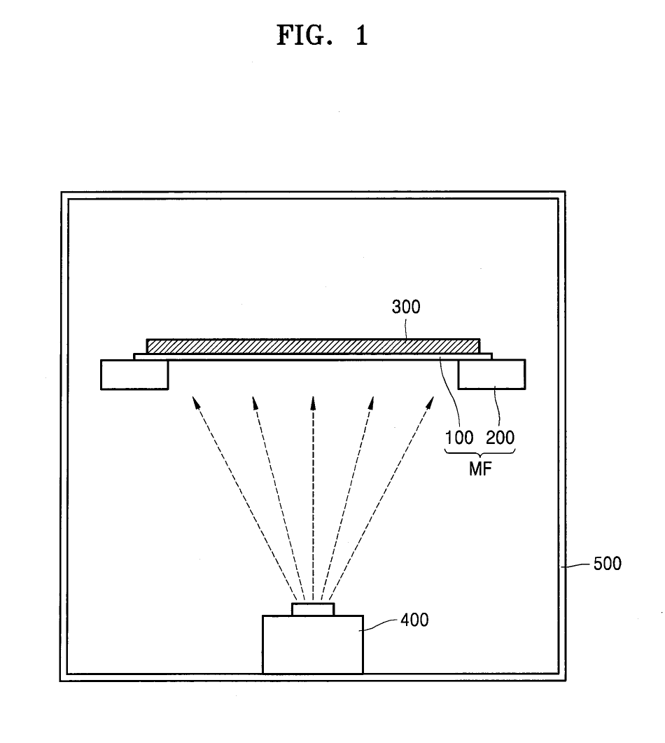

FIG. 1 is a schematic view of a structure of a thin film deposition apparatus including a mask frame assembly MF according to an embodiment of the present invention.

As illustrated in FIG. 1, the thin film deposition apparatus may include the mask frame assembly MF that is used to form a desired pattern on a substrate 300 and a deposition source 400 that ejects a deposition gas toward the substrate 300 in a chamber 500, or the like.

Accordingly, when the deposition source 400 ejects a deposition gas in the chamber 500, the deposition gas passes through the mask frame assembly MF to be deposited on the substrate 300 and form a thin film having a predetermined pattern.

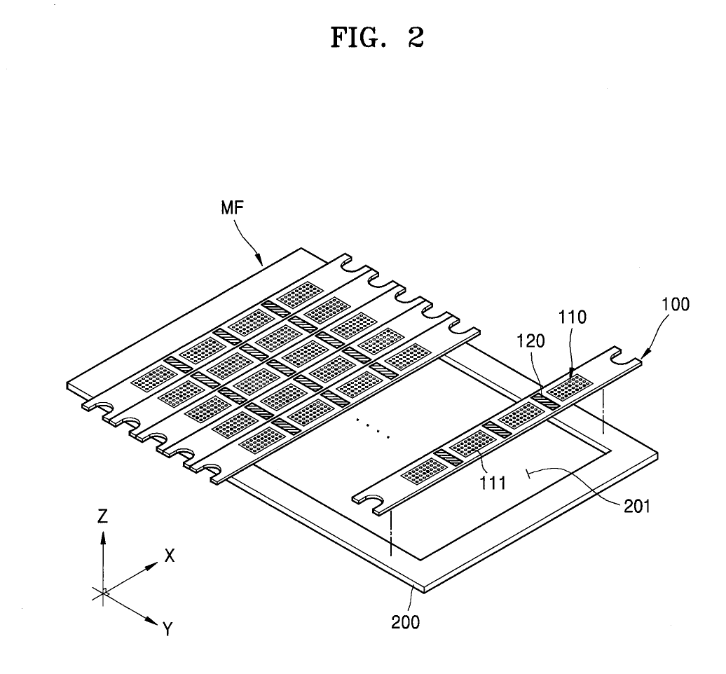

FIG. 2 is a disassembled perspective view illustrating a structure of the mask frame assembly MF.

Referring to FIG. 2, the mask frame assembly MF may include a frame 200 and a plurality of masks 100, each mask 100 having two end portions that are fixed to the frame 200.

The frame 200 is an outer frame of the mask frame assembly MF and has a rectangular shape having an opening 201 in a center thereof. The two end portions of the masks 100 may be fixed to a pair of opposite sides of the frame 200 by welding.

The masks 100 may have a long, stick-shape and include a plurality of pattern portions 110 disposed within the opening 201. As described above, the two end portions of the masks 100 may be welded to the frame 200. The masks 100 may be formed as a large single member. However, when the masks 100 are formed as a large single member, the weight of the masks 100 may result in sagging thereof. Thus, in one or more embodiments, the masks 100 are formed as separate, multiple stick-shaped members as illustrated in FIG. 2.

A shape memory alloy portion 120 may be formed between the pattern portions 110 of each of the masks 100. The shape memory alloy portion 120 reduces wrinkles, or waves, of the masks 100 during deposition. The function of the shape memory alloy portion 120 is described further below.

The pattern portions 110 include a plurality of pattern holes 111. A thin film layer is formed on the substrate 300 that is adhered to the masks 100 as a deposition vapor passes through the pattern holes 111 during deposition.

The masks 100 may be formed of, for example, nickel (Ni) or nickel-cobalt alloy. The pattern holes 111 may have a dot shape as illustrated in FIG. 2, or other shapes, for example, a slit shape.

The shape memory alloy portion 120 is formed of a shape memory alloy, such as nickel-titanium, is bonded on the masks 100, and does not cause any particular effect at room temperature, but deforms (i.e., extends) in a width direction Y at a deposition temperature of between about 40° C. and about 80° C.

When the shape memory alloy portion 120 extends in the width direction Y, waves inherent in the masks 100 are reduced, thereby flattening the masks 100. As such, the masks 100 and the substrate 300 may be closely adhered to each other, thereby allowing deposition of thin films having precise patterns.

The waves inherent in the masks 100 and how the waves are removed by the shape memory alloy portion 120 are described further below.

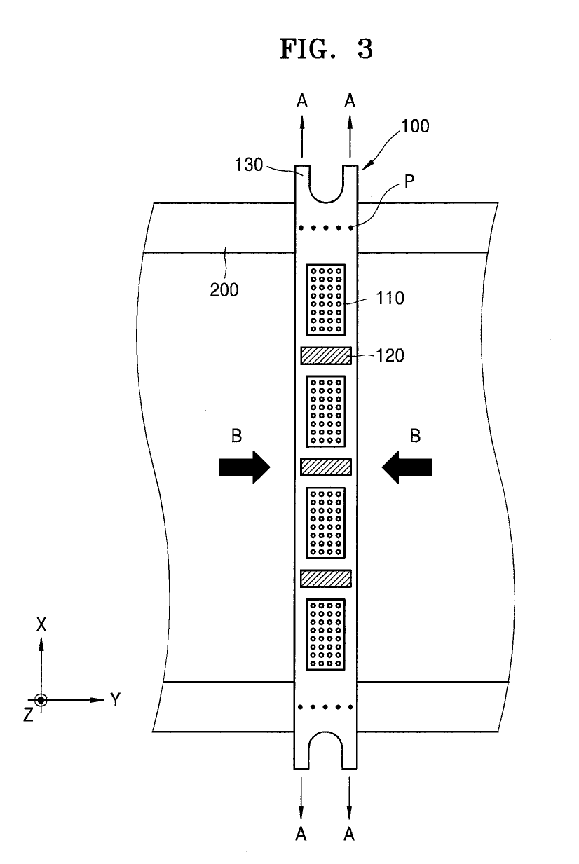

FIG. 3 is a plan view illustrating an operation of coupling the mask 100 of the mask frame assembly MF illustrated in FIG. 2 to the frame 200. Before welding the masks 100 to the frame 200, the masks 100 are pulled taut in a length direction A. A clamping portion 130 is formed at the two end portions of the masks 100. The clamping portion 130 grips the masks 100 during pulling (and welding) and the clamping portion 130 is removed after welding is completed. The masks 100 may be welded to the frame 200 at spot welding portions P.

When pulling the masks 100 in the length direction A, the masks 100 are naturally contracted in a width direction B. If the entire surface of the mask 100 contracts uniformly, very few or very small waves may be generated. However, the masks 100 rarely contract uniformly and contraction will typically vary in different areas of the masks 100, resulting in the formation of waves. Thus, if the masks 100 having waves are used in a deposition operation, adhesion with respect to the substrate 300 is low and it is difficult to form a thin film at a precise (or exact) position.

However, according to one or more embodiments of the present invention, the shape memory alloy portion 120 formed on the masks 100 reduces the waves in the masks 100 during deposition, thereby preventing the above-described problem.

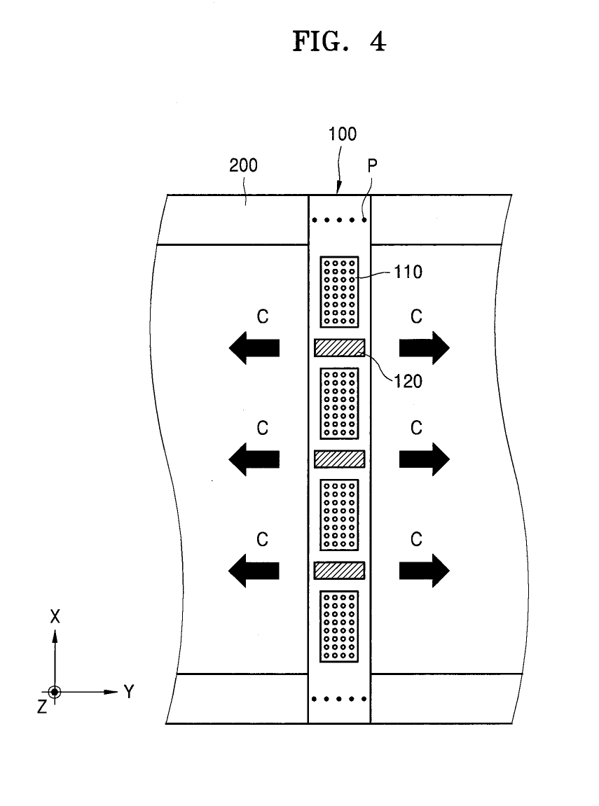

That is, the shape memory alloy portion 120 does not cause any particular effect at a room temperature (i.e., between about 20° C. and about 25° C.), at which bonding of the masks 100 and the frame 200 is performed. However, deposition is typically performed at a higher temperature, for example, between about 40° C. and about 80° C. Referring to FIG. 4, the shape memory alloy portion 120 extends in a direction C opposite to the contraction direction B at a higher temperature of between about 40° C. and about 80° C. This extension of the shape memory alloy portion 120 in the direction C may remove wrinkles from a sheet by pulling the sheet taut in a surface direction, thereby reducing (particularly, quickly reducing) the waves inherent in the masks 100. As adhesive properties between the masks 100 and the substrate 300 are significantly improved, thin films having a precise pattern may be formed.

Thus, although waves may be formed when welding the masks 100 and the frame 200, during deposition, most waves are removed (or reduced) as the shape memory alloy portion 120 extends during deposition , thereby significantly improving adhesive properties between the substrate 300 and the masks 100 during deposition.

The following description refers to preparation of the mask frame assembly MF according to one or more embodiments of the present invention.

The frame 200 is a rectangular frame having an opening 201 in the center thereof. The mask 100 having a stick-shape includes the pattern portions 110, the shape memory alloy portion 120, and the clamping portion 130. The shape memory alloy portion 120 may be bonded to the mask 100 by welding or the like.

The clamping portion 130 at the two end portions of the mask 100 is gripped using a tensioner to pull the mask 100 in the length direction A to flatten the mask 100, and then the mask 100 is fixed to the frame 200 by welding. After the mask 100 is fixed to the frame 200, the clamping portion 130 is cut to be removed. In the same manner, multiple masks 100 are welded to the frame 200 to completely fill (or cover) the opening 201. Although the masks 100 may contract in the width direction B, forming waves, the shape memory alloy portion 120 deforms at a deposition temperature to reduce the waves, thereby improving adhesive properties with respect to the substrate 300 and allowing a stable deposition operation.

The mask frame assembly MF according to one or more embodiments of the present invention may be used in depositing various types of thin films, for example, in forming a pattern of an organic layer or an opposite electrode of an organic light emitting display apparatus.

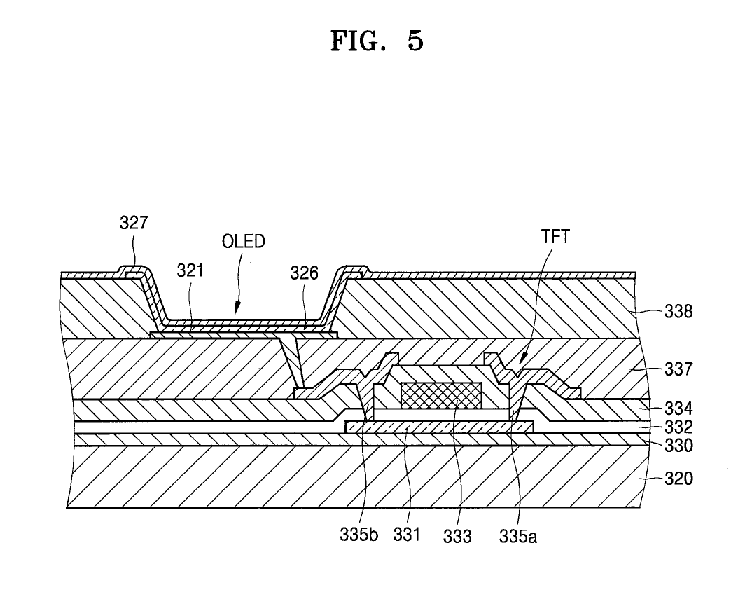

FIG. 5 is a cross-sectional side view illustrating a structure of an organic light emitting display apparatus that may be manufactured using the mask frame assembly MF according to one or more embodiments of the present invention.

Referring to FIG. 5, a buffer layer 330 is formed on a substrate 320, and a thin film transistor (TFT) is formed on the buffer layer 330.

The TFT includes a semiconductor active layer 331, a gate insulation layer 332 formed to cover the semiconductor active layer 331, and a gate electrode 333 on the gate insulation layer 332.

An interlayer insulation layer 334 is formed to cover the gate electrode 333, and source and drain electrodes 335a and 335b are formed on the interlayer insulation layer 334.

The source electrode 335a and the drain electrode 335b respectively contact a source area and a drain area of the semiconductor active layer 331 through contact holes formed in the gate insulation layer 332 and the interlayer insulation layer 334.

A pixel electrode 321 of an organic light emitting device (OLED) is connected to the drain electrode 335b. The pixel electrode 321 is formed on a planarization layer 337, and a pixel defining layer 338 is formed on (or covering) the pixel electrode 321. After forming a predetermined opening portion in the pixel defining layer 338, an organic layer 326 of the OLED is formed, and an opposite electrode 327 is deposited on the organic layer 326.

The organic layer 326 of the OLED may include red (R), green (G), and blue (B) organic emissive layers to express full colors. By using the mask frame assembly MF in which the pattern holes 111 of the pattern portions 110 used for deposition are formed to correspond to the organic layer 326, adhesive properties between the substrate 320 and the masks 100 are increased, thereby obtaining precise patterns.

The mask frame assembly MF may also be used to form the opposite electrode 327 by using the mask frame assembly MF having a pattern corresponding to a pattern of the opposite electrode 327, thereby improving adhesive properties between the substrate 320 and the masks 100 and obtaining precise patterns.

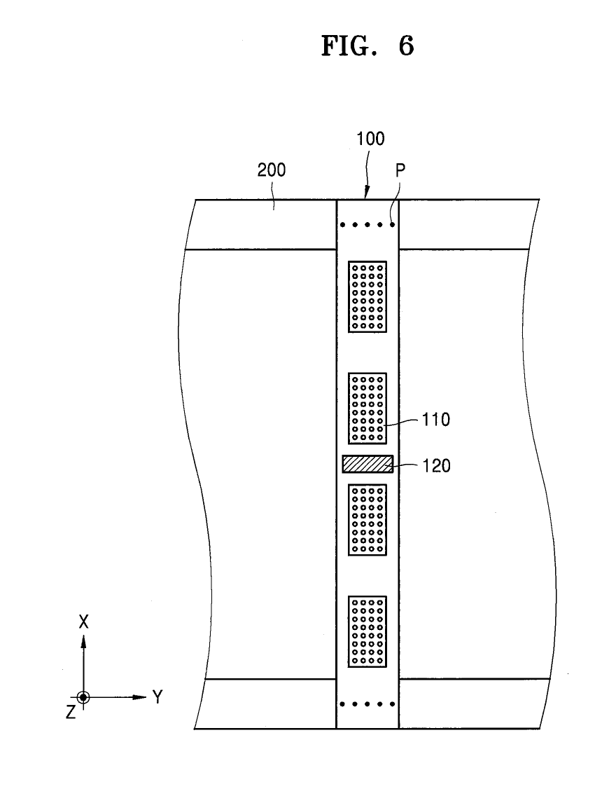

FIG. 6 is a plan view of the mask frame assembly illustrated in FIG. 1 according to another embodiment. While the pattern portions 110 and the shape memory alloy portions 120 may be alternately formed, according to another embodiment, the same effect of reducing waves may be obtained by forming at least one shape memory alloy portion 120 as illustrated in FIG. 6.

It should be understood that the exemplary embodiments described herein should be considered in a descriptive sense only and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope as defined by the following claims.

What is claimed is:

1. A mask frame assembly comprising:
a frame; and
a mask extending in a first direction at a room temperature and coupled to the frame, and
wherein the mask comprises a pattern portion having a pattern hole and a shape memory alloy portion.

2. The mask frame assembly of claim 1, wherein the shape memory alloy portion is configured to extend in a second direction perpendicular to the first direction at a deposition temperature.

3. The mask frame assembly of claim 1, wherein the mask comprises a plurality of pattern portions and a plurality of shape memory alloy portions.

4. The mask frame assembly of claim 3, wherein the plurality of shape memory alloy portions are located between adjacent ones of the plurality of pattern portions.

5. The mask frame assembly of claim 1, wherein the room temperature is between about 20° C. and about 25° C., and the deposition temperature is between about 40° C. and about 80° C.

6. The mask frame assembly of claim 1, wherein the shape memory alloy portion comprises a nickel-titanium alloy material.

7. A method of manufacturing a mask frame assembly, the method comprising:
forming a pattern portion having a pattern hole and a shape memory alloy portion on a mask, the shape memory alloy portion extending in a first direction at a deposition temperature; and
coupling the mask to a frame by extending the mask at a room temperature in a second direction perpendicular to the first direction.

8. The method of claim 7, wherein a plurality of pattern portions and a plurality of shape memory alloy portions are formed on the mask in an alternating pattern.

9. The method of claim 7, wherein the room temperature is between about 20° C. and about 25° C., and the deposition temperature is between about 40° C. and about 80° C.

10. The method of claim 7, wherein the shape memory alloy portion comprises a nickel-titanium alloy material.
